(19) United States
(12) Patent Application Publication
(10) Pub. No.: US 2026/0052627 A1
(43) Pub. Date: Feb. 19, 2026

(54) SEMICONDUCTOR PACKAGE WITH BUFFER STRUCTURE

(71) Applicant: SAMSUNG ELECTRONICS CO., LTD., Suwon-si (KR)

(72) Inventor: Donggyu KIM, Suwon-si (KR)

(73) Assignee: SAMSUNG ELECTRONICS CO., LTD., Suwon-si (KR)

(21) Appl. No.: 19/213,341

(22) Filed: May 20, 2025

(30) Foreign Application Priority Data
Aug. 14, 2024 (KR) 10-2024-0109362

(51) Int. Cl. H05K 1/11; H01L 23/00; H01L 25/04; H05K 1/09; H05K 1/18

(52) U.S. Cl. CPC H05K 1/113; H01L 24/16; H01L 24/32; H01L 24/48; H01L 24/73; H01L 25/042; H05K 1/09; H05K 1/181; H01L 2224/16227; H01L 2224/32225; H01L 2224/48227; H01L 2224/73265; H01L 2924/301; H05K 2201/09481

(57) ABSTRACT

A semiconductor package includes a wiring substrate including a conductive wiring and a plurality of wiring patterns, a terminal pad including a plurality of outermost terminal pads adjacent to each end of the wiring substrate, and a buffer structure interposed between at least two outermost terminal pads from among the plurality of outermost terminal pads. The buffer structure includes a metal. The structure includes a first material having a first ionization tendency that differs from a second ionization tendency of a second material included in at least one of the conductive wiring or the plurality of wiring patterns.

### CROSS-REFERENCE TO RELATED APPLICATIONS

This application claims benefit of priority under 35 U.S. C. § 119 to Korean Patent Application No. 10-2024-0109362, filed on Aug. 14, 2024, in the Korean Intellectual Property Office, the disclosure of which is incorporated by reference herein in its entirety.

### BACKGROUND

### 1. Field

The present disclosure relates generally to a semiconductor package, and more particularly, to a semiconductor package including a buffer structure.

### 2. Description of Related Art

Recently, there has been an increasing demand for portable devices (e.g., smart phones, laptop computers, tablet computers, personal digital assistants (PDA), wearable devices, Internet of Things (IoT) devices, or the like) in the electronic products market, along with a continuing demand for miniaturization (e.g., reduction of form factor) and/or weight reduction of electronic components mounted on these products. In order to potentially achieve miniaturization and/or weight reduction of such electronic components, there may be a demand for techniques that may reduce the size of each of the mounting components, as well as, a semiconductor package technology for integrating a plurality of individual components into one package. In particular, a semiconductor package in which a plurality of components are integrated may need to be miniaturized in addition to exhibit improved bending characteristics, heat dissipation characteristics, electrical characteristics, or the like.

### SUMMARY

One or more example embodiments of the present disclosure provide a semiconductor package with improved electrical characteristics, when compared to related semiconductor packages, and a method of manufacturing the same.

The problem to be addressed by the present disclosure is not limited to the problems mentioned above, and other problems not mentioned may be clearly understood by those skilled in the art from the description below.

According to an aspect of the present disclosure, a semiconductor package includes a wiring substrate including a conductive wiring and a plurality of wiring patterns, a terminal pad including a plurality of outermost terminal pads adjacent to each end of the wiring substrate, and a buffer structure interposed between at least two outermost terminal pads from among the plurality of outermost terminal pads. The buffer structure includes a metal. The structure includes a first material having a first ionization tendency that differs from a second ionization tendency of a second material included in at least one of the conductive wiring or the plurality of wiring patterns.

According to an aspect of the present disclosure, a semiconductor package includes a wiring substrate including a conductive wiring and a plurality of wiring patterns, a plurality of terminal pads, and a buffer structure interposed between at least two outermost terminal pads from among the plurality of outermost terminal pads. The plurality of terminal pads includes a plurality of outermost terminal pads adjacent to each end of the wiring substrate, and an inner terminal pad spaced apart from the plurality of outermost terminal pads. The conductive wiring includes an outer conductive wiring in contact with the buffer structure, and an inner conductive wiring in contact with the inner terminal pad. The outer conductive wiring and the inner conductive wiring are coupled with a same wiring pattern of the plurality of wiring patterns. The buffer structure includes a first material having a first ionization tendency that differs from a second ionization tendency of a second material included in the conductive wiring.

According to an aspect of the present disclosure, a semiconductor package includes a wiring substrate including a conductive wiring and a wiring pattern, a connection layer on the wiring substrate, a semiconductor chip on the connection layer, a plurality of terminal pads including a plurality of outermost terminal pads adjacent to each end of the wiring substrate, a buffer structure in an outermost terminal pad from among the plurality of terminal pads, a pad insulating layer below the wiring substrate, and a plurality of outer terminals coupled with the plurality of terminal pads. The buffer structure includes a metal. The buffer structure is spaced apart from the plurality of outer terminals. The conductive wiring and the wiring pattern include copper (Cu). A first reduction potential of the buffer structure is different from a second reduction potential of the conductive wiring.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a plan view of a semiconductor package, according to embodiments of the present disclosure;

FIG. 2 is a cross-sectional view taken along line A-A′ of FIG. 1, according to embodiments of the present disclosure;

FIG. 3 is an enlarged view of region X of FIG. 2, according to embodiments of the present disclosure;

FIG. 4 is a cross-sectional view corresponding to an enlarged view of region X of FIG. 2, according to embodiments of the present disclosure;

FIG. 5 is a cross-sectional view corresponding to a cross-sectional view taken along line A-A′ of FIG. 1, according to embodiments of the present disclosure; and

FIGS. 6 to 8 are cross-sectional views illustrating a manufacturing process of a semiconductor package, according to embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it indicates that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to”another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more. ” Where only one item is intended, the term “one”or similar language is used.

As used herein, each of the terms “Si₃N₄”, “SiO₂”, and the like may refer to a material made of elements included in each of the terms and is not a chemical formula representing a stoichiometric relationship.

Hereinafter, various embodiments of the present disclosure are described with reference to the accompanying drawings.

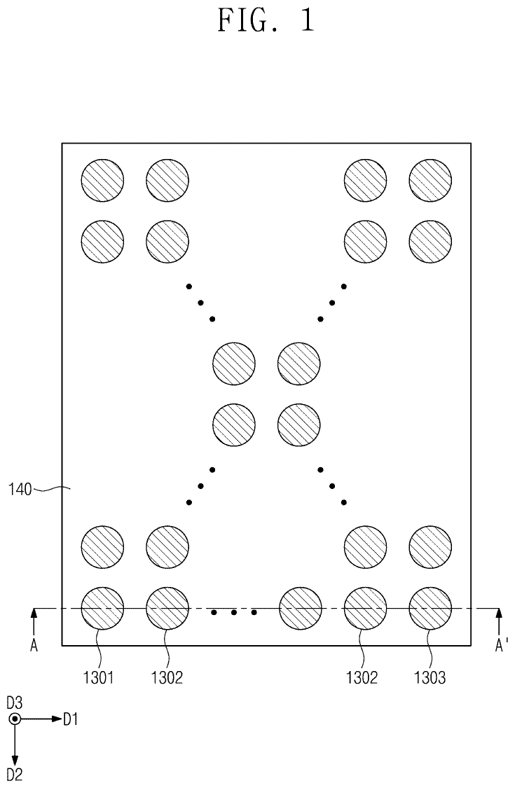

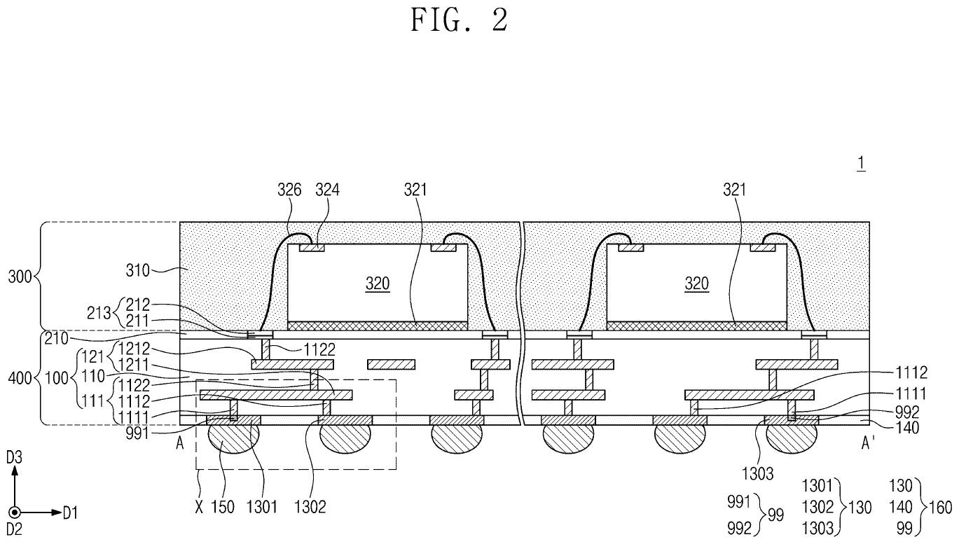

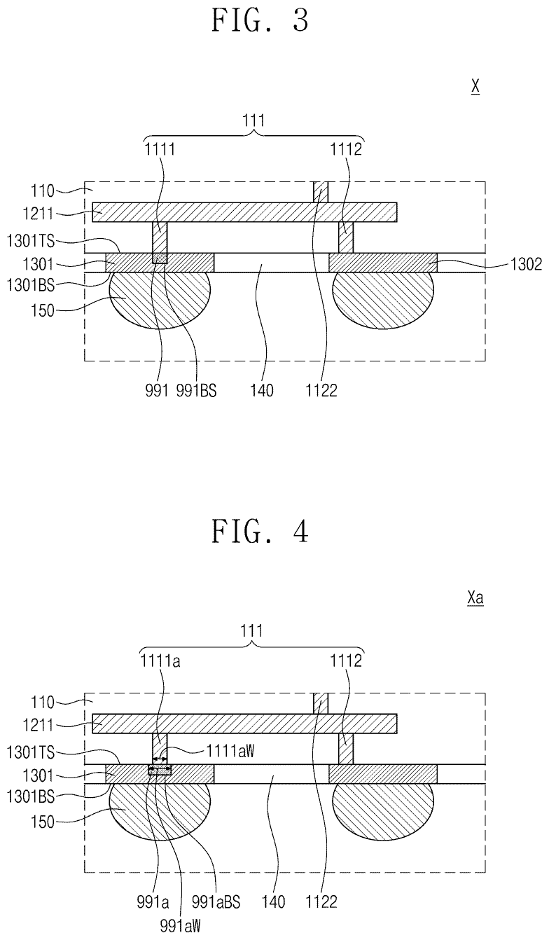

FIG. 1 is a plan view of a semiconductor package, according to embodiments of the present disclosure. FIG. 2 is a cross-sectional view taken along line A-A′ of FIG. 1, according to embodiments of the present disclosure. FIG. 3 is an enlarged view of region X of FIG. 2, according to embodiments of the present disclosure.

Referring to FIGS. 1 to 3, a semiconductor package 1, according to embodiments of the present disclosure, may include a wiring structure 400, a plurality of outer terminals 150 below the wiring structure 400, and a chip structure 300 on the wiring structure 400.

The wiring structure 400 may be provided. The wiring structure 400 may extend in a first direction D1 and a second direction D2 that intersect each other. A third direction D2 may refer to a direction perpendicular to a plane defined by the intersecting first direction D1 and second direction D2.

The wiring structure 400 may include an outer protective layer 160, a wiring substrate 100 on the outer protective layer 160, a connection layer 210 on the wiring substrate 100, and a plurality of wire connection pads 213 in the connection layer 210.

The wiring substrate 100 may be provided. The wiring substrate 100 may be and/or may include, for example, a printed circuit board (PCB). The wiring substrate 100 may have a structure in which an insulating layer and a wiring layer are alternatively stacked.

The wiring substrate 100 may include a wiring insulation layer 110, a plurality of conductive wirings 111 in the wiring insulation layer 110, and a plurality of wiring patterns 121 connected to the plurality of conductive wirings 111.

The wiring insulation layer 110 may be in contact with the connection layer 210 and the outer protective layer 160. The wiring insulation layer 110 may include an insulating material. The wiring insulation layer 110 may include, for example, silicon oxide (SiO₂) and silicon nitride (Si₃N₄). However, the present disclosure is not limited in this regard, and the wiring insulation layer 110 may include other materials and/or combinations of materials.

The plurality of conductive wirings 111 and the plurality of wiring patterns 121 may be disposed in the wiring insulation layer 110. The plurality of conductive wirings 111 and the plurality of wiring patterns 121 may be disposed in multiple layers. That is, the plurality of conductive wirings 111 may be disposed spaced apart in the third direction D3, and the plurality of wiring patterns 121 may be disposed spaced apart in the third direction D3. The plurality of wiring patterns 121 may be interposed between the plurality of conductive wirings 111 spaced apart in the third direction D3.

The plurality of conductive wirings 111 may include an inner conductive wiring 1112 and an outer conductive wiring 1111 disposed at a lowermost surface and may be in contact with the outer protective layer 160, a plurality of connection conductive wirings 1122 spaced apart from the outer protective layer 160, and disposed at a higher level than the inner conductive wiring 1112 and the outer conductive wiring 1111. The inner conductive wiring 1112 and the outer conductive wiring 1111 may be spaced apart from each other. The inner conductive wiring 1112 and the outer conductive wiring 1111 may be connected to the outer protective layer 160, and the plurality of connection conductive wirings 1122 disposed at the highest level may be connected to the plurality of wire connection pads 213. The plurality of conductive wirings 111 may include a conductive material. For example, the plurality of conductive wirings 111 may include, but not be limited to, copper (Cu).

As used herein, being disposed at a higher level may indicate that a vertical distance from the lowermost surface of the plurality of outer terminals 150 is greater. That is, being disposed at a higher level may indicate that a distance from the lowermost surface of the plurality of outer terminals 150 in the third direction D3 is greater.

The plurality of wiring patterns 121 may include an outer wiring pattern 1211 that is in contact with the outer conductive wiring 1111, and a plurality of inner wiring patterns 1212 that is not in contact with the outer conductive wiring 1111. The outer wiring pattern 1211 may be in contact with the outer conductive wiring 1111, the inner conductive wiring 1112, and the plurality of connection conductive wirings 1122. A level of the outer wiring pattern 1211 may be equal to or lower than the level of the plurality of inner wiring patterns 1212. The plurality of wiring patterns 121 that are disposed to be vertically spaced apart may be connected by the plurality of connection conductive wirings 1122. The plurality of inner wiring patterns 1212 may be disposed between the plurality of connection conductive wirings 1122 vertically spaced apart from each other.

The outer wiring pattern 1211 and the plurality of inner wiring patterns 1212 may be disposed on an outer protective layer 160. The outer wiring pattern 1211 may be disposed on the outer wiring pattern 1211 and the plurality of inner wiring patterns 1212. The plurality of connection conductive wirings 1122 may be disposed on the outer wiring pattern 1211, and the plurality of inner wiring patterns 1212 may be disposed on the plurality of connection conductive wirings 1122. The plurality of inner wiring patterns 1212 may be disposed at different levels. The inner conductive wiring 1112 and the outer conductive wiring 1111 may be in contact with the same wiring pattern of the plurality of wiring patterns 121. The plurality of wiring patterns 121 may include a conductive material. The plurality of wiring patterns 121 may include, for example, copper (Cu). However, the present disclosure is not limited in this regard, and the plurality of wiring patterns 121 may include other materials and/or combinations of materials.

The outer protective layer 160 may be provided under the wiring substrate 100. The outer protective layer 160 may include a plurality of terminal pads 130, a pad insulating layer 140 surrounding a side surface of the plurality of terminal pads 130, and a buffer structure 99. The buffer structure 99 may be disposed on a first outermost terminal pad 1301 and a second outermost terminal pad 1303 from among the plurality of terminal pads 130.

The pad insulating layer 140 may be provided under the wiring substrate 100. The pad insulating layer 140 may include an insulating material. For example, the pad insulating layer 140 may include a nitride (e.g., silicon nitride (Si₃N₄)) and/or an oxide (e.g., silicon oxide (SiO₂)). However, the present disclosure is not limited in this regard. The pad insulating layer 140 may surround a side surface of the plurality of terminal pads 130.

The plurality of terminal pads 130 may include a plurality of the first and second outermost terminal pads 1301 and 1303 adjacent to each end of the outer protective layer 160 and a plurality of inner terminal pads 1302 disposed between the spaced first and second outermost terminal pads 1301 and 1303. That is, the plurality of terminal pads 130 may include a plurality of the first and second outermost terminal pads 1301 and 1303 adjacent to each end of the wiring substrate 100 and the plurality of inner terminal pads 1302 disposed between the spaced first and second outermost terminal pads 1301 and 1303. The plurality of terminal pads 130 may include a conductive material. For example, the plurality of terminal pads 130 may include, but not be limited to, copper (Cu).

The first outermost terminal pad 1301 may refer to an outermost terminal pad adjacent to one end of the wiring substrate 100, and the second outermost terminal pad 1303 may refer to an outermost terminal pad adjacent to the other end of the wiring substrate 100.

The buffer structure 99 may be interposed between the first and second outermost terminal pads 1301 and 1303 from among the plurality of terminal pads 130. Among the plurality of conductive wirings 111, the outer conductive wiring 1111 may be connected to the first and second outermost terminal pads 1301 and 1303. The outer conductive wiring 1111 may be in contact with the buffer structure 99. The inner conductive wiring 1112 may be in contact with the plurality of inner terminal pads 1302. The inner conductive wiring 1112 may be connected to the plurality of inner terminal pads 1302. The entire upper surface of the buffer structure 99 may overlap the first and second outermost terminal pads 1301 and 1303.

The buffer structure 99 may include a metal. The material included in the buffer structure 99 may be different from the material included in the plurality of conductive wirings 111 and the plurality of wiring patterns 121. Alternatively or additionally, the material included in the buffer structure 99 may have a different ionization tendency from the material included in the plurality of conductive wirings 111 or the material included in the plurality of wiring patterns 121. For example, the plurality of conductive wirings 111 and the plurality of wiring patterns 121 may include, but not be limited to, copper (Cu), and the buffer structure 99 may include tin (Sn) or platinum (Pt).

The buffer structure 99 disposed in the first outermost terminal pad 1301 may be referred to as a first buffer structure 991. The buffer structure 99 disposed in the second outermost terminal pad 1303 may be referred to as a second buffer structure 992. That is, the buffer structure 99 may include the first buffer structure 991 adjacent to one end of the wiring substrate 100 and the second buffer structure 992 adjacent to the other end of the wiring substrate 100.

The first buffer structure 991 in the first outermost terminal pad 1301 and the second buffer structure 992 in the second outermost terminal pad 1303 may include different materials. A reduction potential of the first buffer structure 991 may be higher than a reduction potential of the second buffer structure 992.

That is, the first buffer structure 991 and the second buffer structure 992 may include different materials. Alternatively or additionally, the first buffer structure 991 and the second buffer structure 992 may include materials having different ionization tendencies. For example, the first buffer structure 991 in the first outermost terminal pad 1301 may include tin (Sn), and the second buffer structure 992 in the second outermost terminal pad 1303 may include platinum (Pt). However, the present disclosure is not limited in this regard, and the first buffer structure 991 and the second buffer structure 992 may include other materials and/or combinations of materials. In an embodiments, a mass of the first buffer structure 991 may be smaller than a mass of the second buffer structure 992.

A connection layer 210 may be provided on the wiring substrate 100, and the plurality of wire connection pads 213 may be disposed in the connection layer 210. A width of the plurality of wire connection pads 213 in the first direction D1 may be greater than a width of the plurality of conductive wirings 111. The plurality of wire connection pads 213 may include a first metal layer 211 on the wiring substrate 100 and a second metal layer 212 on the first metal layer 211. The first metal layer 211 may be in contact with the highest level of the plurality of connection conductive wirings 1122. The first metal layer 211 and the second metal layer 212 may include a conductive material. Alternatively or additionally, the first metal layer 211 and the second metal layer 212 may include different materials. For example, the first metal layer 211 may include, but not be limited to, nickel (Ni), and the second metal layer 212 may include, but not be limited to, gold (Au).

A reduction potential difference between the second metal layer 212 and the buffer structure 99 may be different from a reduction potential difference between the second metal layer 212 and the plurality of conductive wirings 111. For example, a reduction potential difference between the second metal layer 212 and the first buffer structure 991 may be greater than a reduction potential difference between the second metal layer 212 and the plurality of conductive wirings 111, and a reduction potential difference between the second metal layer 212 and the second buffer structure 992 may be smaller than a reduction potential difference between the second metal layer 212 and the plurality of conductive wirings 111.

In an embodiment, during the manufacturing process of the semiconductor package, according to the present disclosure, ionization of a material included in the first buffer structure 991 may occur around the first buffer structure 991. For example, when the first buffer structure 991 includes tin (Sn), ionization of tin (Sn) may occur around the first buffer structure 991.

Furthermore, in the inner conductive wiring 1112 spaced adjacent to the second buffer structure 992, ionization of the material included in the inner conductive wiring 1112 may occur. For example, when the second buffer structure 992 includes platinum (Pt) and the inner conductive wiring 1112 includes copper (Cu), ionization of copper (Cu) may occur in the inner conductive wiring 1112 around the second buffer structure 992.

The chip structure 300 may be placed on the wiring structure 400. The chip structure 300 may include a plurality of semiconductor chips 320 disposed on the connection layer 210, a die attach layer 321 between the plurality of semiconductor chips 320 and the connection layer 210, a chip pad 324 in a semiconductor chip of the plurality of semiconductor chips 320, and a wire 326 connecting the chip pad 324 and the plurality of wire connection pads 213.

The semiconductor chip of the plurality of semiconductor chips 320 may be attached to the connection layer 210 by the die attach layer 321. The semiconductor chip of the plurality of semiconductor chips 320 and the wiring substrate 100 may be electrically connected through the plurality of wire connection pads 213, the wire 326, and the chip pad 324.

The plurality of semiconductor chips 320 may be the same or different types of semiconductor chips. The semiconductor chip of the plurality of semiconductor chips 320 may be and/or may include, for example, a logic chip or a memory chip. The plurality of semiconductor chips 320 may be and/or may include, for example, one of a central processing unit (CPU), a graphics processing unit (GPU), an application specific integrated circuit (ASIC), a dynamic random-access memory (DRAM), a static random-access memory (SRAM), and a NAND flash memory, or the like. However, the present disclosure is not limited in this regard, and the plurality of semiconductor chips may include other types of chips that may perform other functions.

The plurality of outer terminals 150 may be disposed under the wiring structure 400. The plurality of outer terminals 150 may be in contact with the plurality of terminal pads 130. The plurality of outer terminals 150 may be electrically connected to the plurality of conductive wirings 111 and the plurality of wiring patterns 121 in the wiring substrate 100 through the plurality of terminal pads 130. The plurality of outer terminals 150 and the buffer structure 99 may be spaced apart from each other.

The plurality of outer terminals 150 may include solder balls or solder bumps. Depending on the type and arrangement of the plurality of outer terminals 150, the plurality of outer terminals 150 may be provided in the form of a ball grid array (BGA), a fine ball-grid array (FBGA), or a land grid array (LGA). An outer connection terminal 90 may be and/or may include an alloy including, but not being limited to, at least one of tin (Sn), silver (Ag), copper (Cu), nickel (Ni), bismuth (Bi), indium (In), antimony (Sb), or cerium (Ce).

Continuing to refer to FIG. 3, the first outermost terminal pad 1301 and the first buffer structure 991 are illustrated. The structure described below with reference to the first outermost terminal pad 1301 may also be applied to the second outermost terminal pad 1303 and the second buffer structure 992.

A level of the upper surface 1301TS of the first outermost terminal pad 1301 may be higher than a level of the lower surface 991BS of the first buffer structure 991. The level of the lower surface 991BS of the first buffer structure 991 may be higher than a level of the lower surface 1301BS of the first outermost terminal pad 1301. No buffer structure 99 may be interposed in the plurality of inner terminal pads 1302. A width of the first buffer structure 991 may be substantially similar and/or the same as a width of the outer conductive wiring 1111. As used herein, substantially similar may refer to a value being within an error range of about 10%.

As ionization may occur in the first buffer structure 991 and ionization may not occur in the second buffer structure 992, the level of the lower surface 991BS of the first buffer structure 991 may be higher than the level of the lower surface of the second buffer structure 992.

FIG. 4 is a cross-sectional view corresponding to an enlarged view of region X of FIG. 2, according to embodiments of the present disclosure. Region Xa of FIG. 4 may include and/or may be similar in many respects to the region X described above with reference to FIGS. 1 to 3, and may include additional features not mentioned above. Consequently, repeated descriptions of the region Xa described above with reference to FIGS. 1 to 3 may be omitted for the sake of brevity.

Referring to FIG. 4, another embodiment of the first outermost terminal pad 1301 and a first buffer structure 991a is illustrated. As shown in FIG. 4, a level of the upper surface 1301TS of the first outermost terminal pad 1301 may be higher than a level of the lower surface 991aBS of the first buffer structure 991a. The level of the lower surface 991aBS of the first buffer structure 991a may be higher than the level of the lower surface 1301BS of the first outermost terminal pad 1301. A width 991aW of the first buffer structure 991a may be greater than a width 1111aW of the outer conductive wiring 1111a.

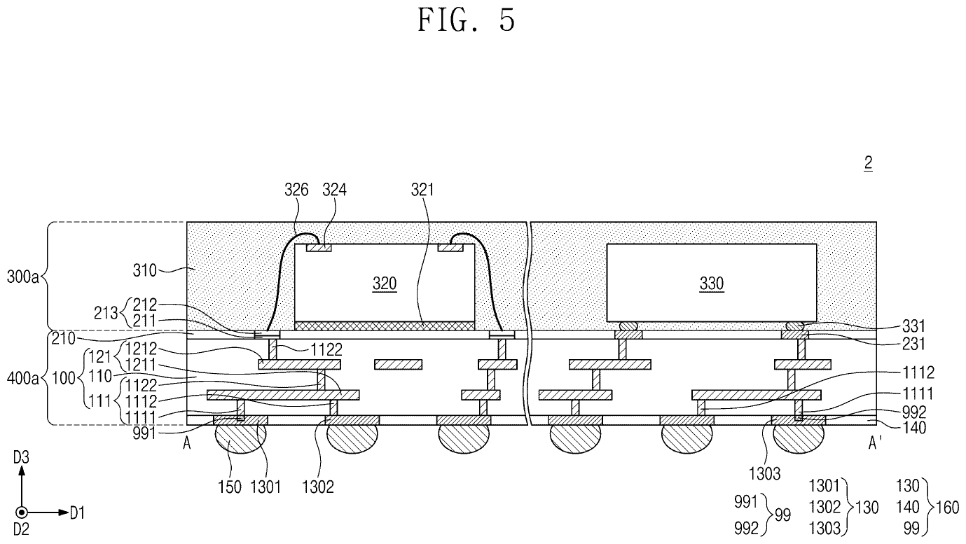

FIG. 5 is a cross-sectional view corresponding to a cross-sectional view taken along line A-A′ of FIG. 1, according to embodiments of the present disclosure. Semiconductor package 2 of FIG. 5 may include and/or may be similar in many respects to the semiconductor package 1 described above with reference to FIGS. 1 to 4, and may include additional features not mentioned above. Consequently, repeated descriptions of the semiconductor package 2 described above with reference to FIGS. 1 to 4 may be omitted for the sake of brevity.

Referring to FIG. 5, the semiconductor package 2, according to embodiments of the present disclosure, is provided. A wiring structure 400a of the semiconductor package 2 may further include a bump pad 231 in the connection layer 210, and a chip structure 300a of the semiconductor package 2 may further include a bump 331. Some of the plurality of semiconductor chips 320 disposed on the connection layer 210 may be connected to the plurality of conductive wirings 111 through the plurality of wire connection pads 213. Among the plurality of semiconductor chips 320, other semiconductor chips that may not be connected to the plurality of wire connection pads 213 may be connected to the plurality of conductive wirings 111 through the bump 331. That is, one or more of the semiconductor chips from among the plurality of semiconductor chips 320 may be attached to the connection layer 210 by the bump 331.

In the semiconductor packages, according to the embodiments of the present disclosure, as the buffer structure 99 includes materials having different ionization tendencies from the plurality of conductive wirings 111 and the plurality of wiring patterns 121, the ionization near the plurality of conductive wirings 111 and the plurality of wiring patterns 121 may be controlled through the buffer structure 99 during the manufacturing process.

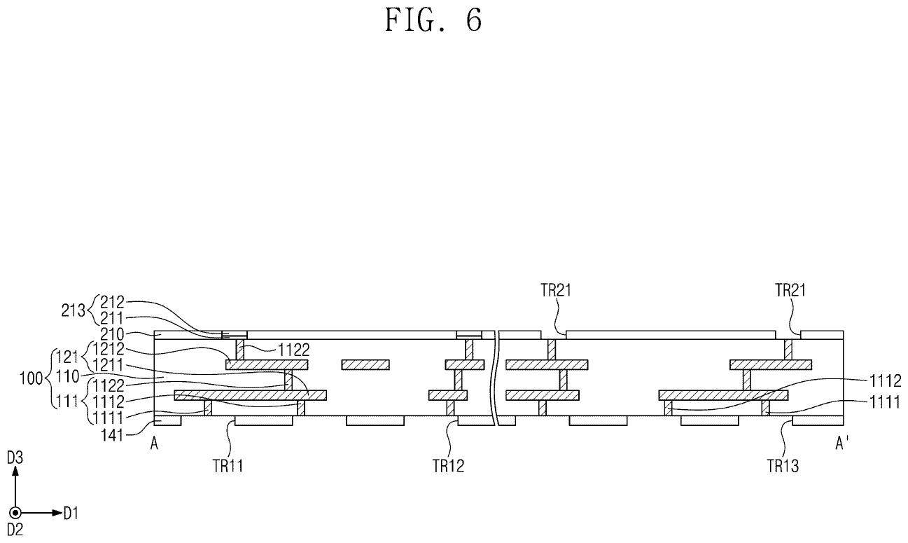

FIGS. 6 to 8 are cross-sectional views illustrating a manufacturing process of a semiconductor package, according to embodiments of the present disclosure. In particular, a method of manufacturing the semiconductor package 2, according to embodiments of FIG. 5, is illustrated.

Referring to FIG. 6, a wiring substrate 100 and a connection layer 210 in which the plurality of wire connection pads 213 are formed may be provided. A connection trench TR21 may be formed in the connection layer 210. An upper surface of the plurality of connection conductive wirings 1122 may be exposed by the connection trench TR21.

A preliminary pad insulating layer 141 may be provided below the wiring substrate 100. A first pad trench TR11, a plurality of second pad trenches TR12, and a third pad trench TR13 may be formed in the preliminary pad insulating layer 141.

The first pad trench TR11 may be formed at one end of the wiring substrate 100. The third pad trench TR13 may be formed at the other end of the wiring substrate 100. The plurality of second pad trenches TR12 may be disposed between the first pad trench TR11 and the third pad trench TR13.

A lower surface of the outer conductive wiring 1111 disposed at one end of the wiring substrate 100 may be exposed by the first pad trench TR11. A lower surface of the outer conductive wiring 1111 disposed at the other end of the wiring substrate 100 may be exposed by the third pad trench TR13. A lower surface of an inner conductive wiring 1112 may be exposed by the plurality of second pad trenches TR12.

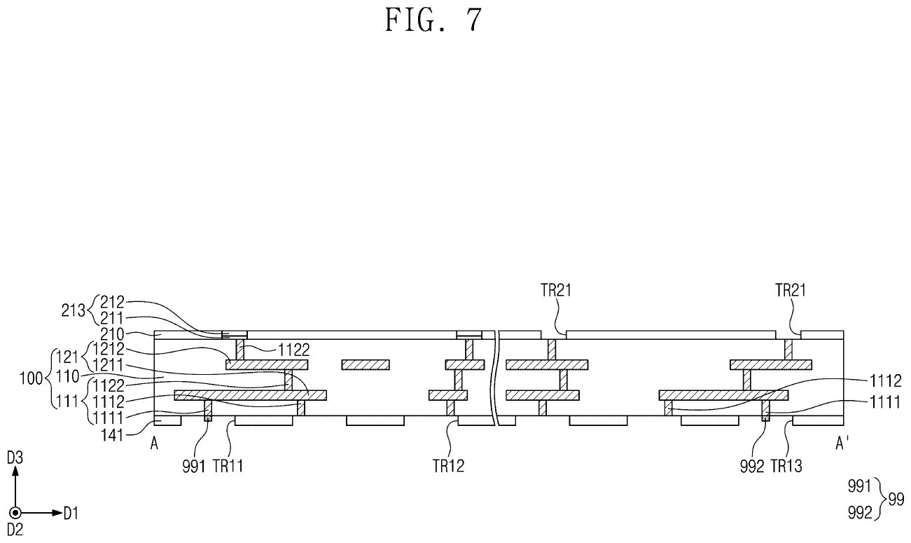

Referring to FIG. 7, a first buffer structure 991 may be formed on the lower surface of the outer conductive wiring 1111 exposed by the first pad trench TR11. A second buffer structure 992 may be formed on the lower surface of the outer conductive wiring 1111 exposed by the third pad trench TR13.

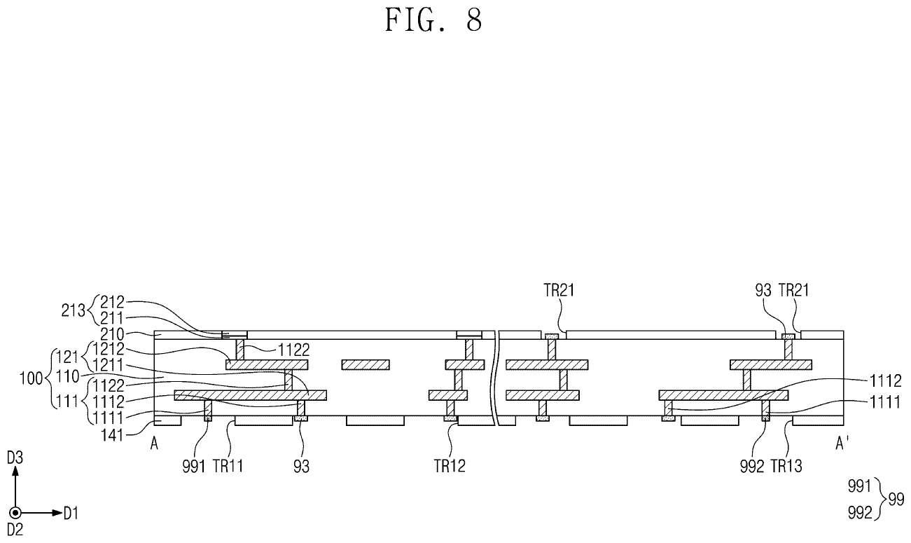

Referring to FIG. 8, a protective layer 93 may be formed in the plurality of second pad trenches TR12 and the connection trench TR21 excluding the first pad trench TR11 in which the first buffer structure 991 is formed and the third pad trench TR13 in which the second buffer structure 992 is formed. The protective layer 93 may include an organic material. The protective layer 93 may be formed to cover the inner conductive wiring 1112 exposed by the plurality of second pad trenches TR12 and the plurality of connection conductive wirings 1122 exposed by the connection trench TR21. The protective layer 93 may be formed so as not to fill both the plurality of second pad trenches TR12 and the connection trench TR21.

As described above, as an ionization tendency of the buffer structure 99 and an ionization tendency of the plurality of conductive wirings 111 are different, a thickness of the protective layer 93 may be freely adjusted. For example, the ionization tendency of the first buffer structure 991 may be greater than the ionization tendency of the plurality of conductive wirings 111. The ionization tendency of the second buffer structure 992 may be less than the ionization tendency of the plurality of conductive wirings 111. In this case, ionization of the material included in the first buffer structure 991 may occur around the first buffer structure 991. Ionization of the material included in the inner conductive wiring 1112 adjacent to and spaced from the second buffer structure 992 may occur. Therefore, the protective layer 93 formed on the inner conductive wiring 1112 adjacent to the first buffer structure 991 may be relatively thin. The protective layer 93 formed on the inner conductive wiring 1112 adjacent to the second buffer structure 992 may be relatively thick.

Referring again to FIG. 5, thereafter, a first outermost terminal pad 1301 may be formed in the first pad trench TR11 and a second outermost terminal pad 1303 may be formed in the third pad trench TR13. A plurality of inner terminal pads 1302 may be formed in the plurality of second pad trenches TR12. A bump 331 may be formed in the connection trench TR21. During the process of forming the pads, the protective layer 93 described above may be oxidized and removed. Through this, a wiring structure 400a may be formed.

Thereafter, a chip structure 300 may be attached on the wiring structure 400a, and the plurality of outer terminals 150 may be attached under the wiring structure 400a. By attaching the plurality of outer terminals 150 to the plurality of terminal pads 130, the semiconductor package 2 of FIG. 5 may be formed.

The semiconductor package, according to embodiments of the present disclosure, may have the buffer structure interposed in the outermost terminal pad. In this case, the ionization tendency of the conductive wiring of the buffer structure and the substrate of the semiconductor package may be different.

As a result, the thickness of the protective layer may be adjusted during the manufacturing process of the semiconductor package. The electrical characteristics of the semiconductor package may be improved.

While embodiments are described above, a person skilled in the art may understand that many modifications and variations may be made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor package, comprising:
a wiring substrate comprising a conductive wiring and a plurality of wiring patterns;
a terminal pad comprising a plurality of outermost terminal pads adjacent to each end of the wiring substrate; and
a buffer structure interposed between at least two outermost terminal pads from among the plurality of outermost terminal pads,
wherein the buffer structure comprises a metal, and
wherein the buffer structure comprises a first material having a first ionization tendency that differs from a second ionization tendency of a second material comprised by at least one of the conductive wiring or the plurality of wiring patterns.

2. The semiconductor package of claim 1, wherein the plurality of outermost terminal pads comprises:
a first outermost terminal pad adjacent to a first end of the wiring substrate; and
a second outermost terminal pad adjacent to a second end of the wiring substrate, and
wherein the buffer structure comprises:
a first buffer structure adjacent to the first outermost terminal pad; and
a second buffer structure adjacent to the second outermost terminal pad, and
wherein the first buffer structure and the second buffer structure comprise different materials.

3. The semiconductor package of claim 2, wherein the first buffer structure comprises tin (Sn), and
wherein the second buffer structure comprises platinum (Pt).

4. The semiconductor package of claim 1, further comprising:
an inner terminal pad between the at least two outermost terminal pads and spaced apart from each other,
wherein the conductive wiring comprises:
an inner conductive wiring coupled with the inner terminal pad; and
an outer conductive wiring coupled with a first outermost terminal pad of the at least two outermost terminal pads, and
wherein the inner conductive wiring and the outer conductive wiring are in contact with a same wiring pattern of the plurality of wiring patterns.

5. The semiconductor package of claim 1, wherein the conductive wiring comprises:
an outer conductive wiring in contact with the buffer structure;
an inner conductive wiring spaced apart from the outer conductive wiring; and
a connection conductive wiring coupling the plurality of wiring patterns,
wherein the plurality of wiring patterns comprises:
an outer wiring pattern in contact with the outer conductive wiring; and
an inner wiring pattern spaced apart the outer conductive wiring, and
wherein the outer wiring pattern is in contact with the inner conductive wiring and the connection conductive wiring.

6. The semiconductor package of claim 5, wherein the connection conductive wiring comprises a plurality of connection conductive wirings spaced apart vertically, and
wherein the plurality of wiring patterns is disposed between the plurality of connection conductive wirings.

7. The semiconductor package of claim 1, further comprising:
a connection layer on the wiring substrate;
a wire connection pad in the connection layer;
a bump on the connection layer; and
a plurality of semiconductor chips on the connection layer,
wherein a first semiconductor chip of the plurality of semiconductor chips is coupled with the conductive wiring through the wire connection pad, and
wherein a second semiconductor chip of the plurality of semiconductor chips is coupled with the conductive wiring through the bump.

8. The semiconductor package of claim 1, wherein an upper surface of the buffer structure at least partially overlaps the at least two outermost terminal pads.

9. A semiconductor package, comprising:
a wiring substrate comprising a conductive wiring and a plurality of wiring patterns;
a plurality of terminal pads comprising:
a plurality of outermost terminal pads adjacent to each end of the wiring substrate; and
an inner terminal pad spaced apart from the plurality of outermost terminal pads; and
a buffer structure interposed between at least two outermost terminal pads from among the plurality of outermost terminal pads,
wherein the conductive wiring comprises:
an outer conductive wiring in contact with the buffer structure; and
an inner conductive wiring in contact with the inner terminal pad,
wherein the outer conductive wiring and the inner conductive wiring are coupled with a same wiring pattern of the plurality of wiring patterns, and
wherein the buffer structure comprises a first material having a first ionization tendency that differs from a second ionization tendency of a second material comprised by the conductive wiring.

10. The semiconductor package of claim 9, wherein the plurality of outermost terminal pads comprises:
a first outermost terminal pad adjacent to a first end of the wiring substrate; and
a second outermost terminal pad adjacent to a second end of the wiring substrate,
wherein the buffer structure comprises:
a first buffer structure adjacent to the first outermost terminal pad; and
a second buffer structure adjacent the second outermost terminal pad, and
wherein a first reduction potential of the first buffer structure is greater than a second reduction potential of the second buffer structure.

11. The semiconductor package of claim 10, wherein the conductive wiring and the plurality of terminal pads comprise copper (Cu),
wherein the first buffer structure comprises tin (Sn), and
wherein the second buffer structure comprises platinum (Pt).

12. The semiconductor package of claim 11, wherein a first mass of the first buffer structure is smaller than a second mass of the second buffer structure.

13. The semiconductor package of claim 9, further comprising:
a connection layer on the wiring substrate;
a first metal layer in the connection layer; and
a second metal layer on the first metal layer,
wherein the buffer structure comprises:
a first buffer structure adjacent to a first of the wiring substrate; and
a second buffer structure adjacent to a second end of the wiring substrate, and
wherein a first reduction potential difference between the second metal layer and the first buffer structure is greater than a second reduction potential difference between the second metal layer and the conductive wiring.

14. The semiconductor package of claim 9, further comprising:
a connection layer on the wiring substrate;
a plurality of semiconductor chips on the connection layer; and
a die attach layer and a bump on the connection layer,
wherein a first semiconductor chip from among the plurality of semiconductor chips is coupled with the connection layer by the die attach layer, and
wherein a second semiconductor chip from among the plurality of semiconductor chips is coupled with the connection layer by the bump.

15. The semiconductor package of claim 9, wherein a first width of the buffer structure is greater than a second width of the outer conductive wiring.

16. The semiconductor package of claim 9, wherein a first level of a first lower surface of the buffer structure is higher than a second level of a second lower surface of the at least two outermost terminal pads.

17. A semiconductor package, comprising:
a wiring substrate comprising a conductive wiring and a wiring pattern;
a connection layer on the wiring substrate;
a semiconductor chip on the connection layer;
a plurality of terminal pads comprising a plurality of outermost terminal pads adjacent to each end of the wiring substrate;
a buffer structure in an outermost terminal pad from among the plurality of terminal pads;
a pad insulating layer below the wiring substrate; and
a plurality of outer terminals coupled with the plurality of terminal pads,
wherein the buffer structure comprises a metal,
wherein the buffer structure is spaced apart from the plurality of outer terminals,
wherein the conductive wiring and the wiring pattern comprise copper (Cu), and
wherein a first reduction potential of the buffer structure is different from a second reduction potential of the conductive wiring.

18. The semiconductor package of claim 17, wherein the outermost terminal pad comprises:
a first outermost terminal pad adjacent to a first end of the wiring substrate; and
a second outermost terminal pad adjacent to a second end of the wiring substrate,
wherein the buffer structure comprises:
a first buffer structure adjacent to the first outermost terminal pad; and
a second buffer structure adjacent to the second outermost terminal pad,
wherein the first buffer structure comprises tin (Sn), and
wherein the second buffer structure comprises platinum (Pt).

19. The semiconductor package of claim 18, wherein a first level of a first lower surface of the buffer structure is higher than a second level of a second lower surface of the outermost terminal pad.

20. The semiconductor package of claim 18, wherein a first level of a first lower surface of the first buffer structure is higher than a second level of a second lower surface of the second buffer structure.
